(19) United States
(12) Patent Application Publication
(10) Pub. No.: US 2007/0095389 A1
(43) Pub. Date: May 3, 2007

(54) Transparent electrode for solar cells, manufacturing method thereof, and semiconductor electrode comprising the same

(76) Inventors: Sung Hen Cho, Seoul (KR); Ki Yong Song, Seoul (KR); Chang Ho Noh, Suwon-Si (KR); Jin Young Kim, Suwon-Si (KR)

Correspondence Address: CANTOR COLBURN, LLP, 55 GRIFFIN ROAD SOUTH, BLOOMFIELD, CT, 06002, US

(21) Appl. No.: 11/454,527

(22) Filed: Jun. 16, 2006

(30) Foreign Application Priority Data
Nov. 1, 2005 (KR) 2005-103845

(51) Int. Cl. H01L 31/00

(52) U.S. Cl. 136/263

(57) ABSTRACT

Disclosed herein is a transparent electrode for solar cells, comprising a transparent electrode, a photocatalytic layer formed on the transparent electrode and comprising a photocatalytic compound, a metal mesh layer formed on the photocatalytic layer, and an electrically conductive layer formed of an electrically conductive material coated on the metal mesh layer. Disclosed herein too is a manufacturing method thereof and a semiconductor electrode comprising the same. The disclosed transparent electrode includes a metal mesh layer formed in an existing transparent electrode for solar cells, and thus has low resistance without a reduction in transmittance. Accordingly, a solar cell that utilizes the disclosed transparent electrode has high-efficiency characteristics.

### BACKGROUND OF THE INVENTION

This non-provisional application claims priority under 35 U.S.C. § 119(a) to Korean Patent Application No. 2005-103845 filed on Nov. 1, 2005, the entire contents of which are hereby incorporated by reference.

1. Field of the Invention

The present invention relates to a transparent electrode for solar cells, a manufacturing method thereof and a semiconductor electrode comprising the same. The present invention more particularly relates to a transparent electrode for solar cells, wherein a metal mesh layer is formed in the existing transparent electrode for solar cells thereby displaying a high transmittance and electrical conductivity, as well as a manufacturing method thereof and a semiconductor electrode comprising the same.

2. Description of the Prior Art

Solar cells, which comprise photoelectric conversion elements that convert solar light (visible electromagnetic radiation) into electricity, are sustainable and eco-friendly, and are therefore being utilized with increasing frequency. Monocrystalline, polycrystalline or amorphous silicon solar cells have mainly been used, but these have high manufacturing costs and display only limited improvement with respect to energy conversion efficiency. For this reason, organic solar cells are being actively considered as replacements for silicon solar cells.

Among organic solar cells, a dye-sensitized solar cell having high energy conversion efficiency, low manufacturing costs and long-term stability is actively being considered as a replacement for silicon solar cells.

The dye-sensitized solar cell is a photoelectrochemical solar cell comprising a semiconductor electrode that is formed on a transparent electrode. The dye-sensitized solar cell further comprises a light-absorbing layer adsorbed with metal oxide nanoparticles, a counter electrode and a redox electrolyte filled in the space between the transparent and the counter electrode.

In this dye-sensitized solar cell, the transparent electrode is made of an electrically conductive material coated on a transparent substrate. The transparent electrode is generally a glass electrode coated with indium tin oxide. Indium tin oxide is the electrically conductive material. The indium tin oxide electrode has a transmittance and conductivity suitable for use as an electrode in solar cells. However, the indium tin oxide electrode has problems in that it impedes the migration of electrons due to its high electrical resistance, and thus cannot provide a uniform electrical current when used in large-area applications. It is also manufactured at a high cost through a relatively complex process.

In an attempt to solve these problems, U.S. Patent Application No. 2003-0230337 discloses a solar cell wherein at least one of two electrodes in a photovoltaic cell is a mesh electrode. However, since the mesh pattern is formed through a photoresist or etching process, the manufacturing process thereof is complex, which increases manufacturing costs.

### SUMMARY OF THE INVENTION

Accordingly, the present invention provides a transparent electrode for solar cells, which has high transmittance and low electrical resistance characteristics while providing a good UV-blocking performance that reduces the deterioration of the dye and the electrolyte. This improves the solar cell and extends the life cycle of the solar cell.

The present invention further provides a method for manufacturing a transparent electrode for solar cells, which can be used to manufacture the transparent electrode inexpensively via a simple process.

The present invention provides a semiconductor electrode for solar cells, which comprises a transparent electrode.

In one aspect, the present invention provides a transparent electrode for solar cells, comprising: a transparent substrate; a photocatalytic layer made of a photocatalytic compound formed on the transparent substrate; a metal mesh layer formed on the photocatalytic layer; and a conductive layer formed of an electrically conductive material coated on the metal mesh layer.

In the inventive transparent electrode, the photocatalytic layer is formed of a photocatalytic compound, which is activated upon irradiation with light to show increased reactivity. Preferred examples of the photocatalytic compound include Ti-containing organometallic compounds that can form transparent TiO₂by thermal treatment.

In another aspect, the present invention provides a method for manufacturing a transparent electrode for solar cells, that comprises the steps of: coating a photocatalytic compound on a transparent substrate to form a photocatalytic layer; coating a water-soluble polymer on the photocatalytic layer to form a water-soluble polymer layer; selectively exposing the photocatalytic layer and the water-soluble polymer layer to light; plating the exposed substrate with a metal to form a metal mesh layer; and coating an electrically conductive material on the metal mesh layer to form an electrically conductive layer.

In still another aspect, the present invention provides a semiconductor electrode for solar cells, comprising said transparent electrode and a light-absorbing layer.

### BRIEF DESCRIPTION OF THE DRAWINGS

The above features and advantages of the present invention will be more clearly understood from the following detailed description taken in conjunction with the accompanying drawings, in which:

FIG. 1 is a schematic cross-sectional view of a transparent electrode according to one embodiment of the present invention;

FIG. 2 is a schematic cross-sectional view of a solar cell comprising a transparent electrode according to the embodiment of the present invention;

FIG. 3 is a photograph of the inventive transparent electrode manufactured in the Example;

FIG. 4 is a graphic diagram showing measurement results for the inventive transparent electrode manufactured in the Example; and

FIG. 5 is a graphic diagram showing the absorbance of the inventive transparent electrode manufactured in the Example at various wavelengths.

### DETAILED DESCRIPTION OF THE INVENTION

This invention will be described in further detail with reference to the accompanying drawings.

A transparent electrode according to the present invention includes a metal mesh film formed on an existing transparent electrode that comprises an electrically conductive material coated on a transparent substrate, and displays low electrical resistance characteristics without a reduction in visible light transmittance. Accordingly, using a transparent electrode having a high light transmittance and electrical conductivity in solar cells, can provide a high-efficiency solar cell having excellent photoelectric characteristics.

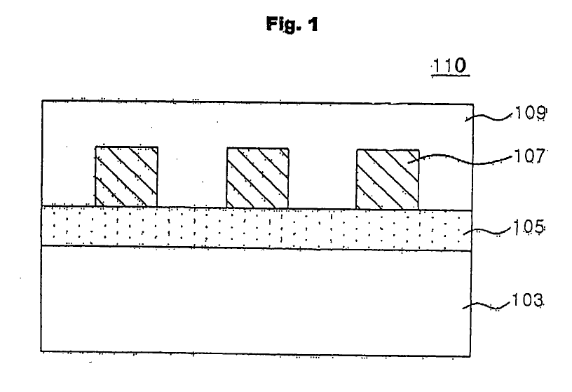

FIG. 1 is a schematic cross-sectional view of a transparent electrode for solar cells according to one embodiment of the present invention. As shown in FIG. 1, the transparent electrode 110 comprises a transparent substrate 103, a photocatalytic layer 105, a metal mesh layer 107, and a conductive layer 109. The electrode of FIG. 1 can be used in a dye-sensitized solar cell.

Examples of suitable transparent substrates that can be used include transparent inorganic substrates such as quartz and glass, or transparent plastic substrates such as polymethylmethacrylate (PMMA), polyethylene terephthalate (PET), polyethylene naphathalate (PEN), polyethylene sulfone (PES), polycarbonate, polystyrene, and polypropylene. When a flexible substrate is used, a flexible dye-sensitized solar cell can be manufactured.

The photocatalytic layer 105 is formed of a photocatalytic compound. As used herein, the term “photocatalytic compound” refers to a compound that, before exposure to light, is inactive, but when irradiated with light such as ultraviolet light, is activated to show an increase in reactivity. The photocatalytic compound, when exposed to ultraviolet light, will have electrons excited in the exposed portion so as to have potential such as reducing potential. Thus, if the photocatalytic layer 105 is selectively exposed to light through a photomask having fine patterns formed thereon, the reduction of metal ions such as platinum and palladium will occur only at the exposed portion, so as to permit the metal mesh layer 107 to be formed in a subsequent step.

Specific examples of this photocatalytic compound may include Ti-containing organometallic compounds that can form transparent TiO₂ upon thermal treatment. Examples of the photocatalytic compound include tetraisopropyltitanate, tetra-n-butyl titanate, tetrakis(2-ethyl-hexyl)titanate, polybutyltitanate, or a combination comprising at least one of the photocatalytic compound.

In the inventive transparent electrode, the photocatalytic layer 105 is preferably formed on the transparent substrate to have a thickness of about 10 to about 100 nanometers (nm). In one embodiment, the photocatalytic layer has a thickness of about 20 to about 90 nm. In another embodiment, the photocatalytic layer has a thickness of about 30 to about 70 nm.

The metal mesh layer 107 is formed by selectively exposing the photocatalytic layer 105 to light through, for example, a photomask, and thus shows a constant metal mesh pattern. The inventive transparent electrode 110 includes the metal mesh layer 107 as described above, and displays high transmittance of incident visible light and low electrical resistance characteristics.

The metal mesh pattern of the metal mesh layer 107 may be a pattern where pluralities of openings are regularly or irregularly repeated. The shape of these openings is not necessarily limited to a square shape and may be any shape such as a circular, triangular or zigzag shape.

The linewidth, density or the like of the metal mesh layer 107 can be controlled in view of the desired transmittance, flexibility, mechanical strength, or the like of the transparent electrode. The linewidth of the metal mesh layer is not specifically limited and may be in a range of, for example, about 3 to about 50 micrometers (μm). In one embodiment, the linewidth can be about 5 to about 45 micrometers. In another embodiment, the line width can be about 10 to about 40 micrometers.

The metal mesh layer 107 may also have a multilayer structure comprising at least two layers. In the event of the metal mesh layer comprising multiple layers, the layers may be plated with different metals. If the metal mesh layer has, for example, a two-layer structure, the first metal mesh layer may comprise Ni, Pd, Sn, Cr or an alloy thereof, and the second metal mesh layer may comprise Cu, Ag, Au or an alloy thereof. To improve the contact resistance between the second metal mesh layer and the conductive layer, the second layer may also be plated with Ni, Pd, Sn, Cr or an alloy thereof so as to form a third metal layer.

The conductive material for forming the conductive layer 109 formed on the metal mesh layer 107 can be indium tin oxide (ITO), fluorine-doped tin oxide (FTO), ZnO-Ga₂O₃, ZnO-Al₂0₃, SnO₂-Sb₂O₃, or the like, or a combination comprising at least one of the foregoing conductive materials. In addition to these materials, a conductive polymer such as PEDOT (poly-3,4-ethylenedioxythiophene), polyaniline, polypyrrole, polyacetylene, or a combination comprising at least one of the foregoing conductive polymers can also be used. Blends and copolymers of conductive polymers can also be used.

A semiconductor electrode for solar cells comprises a light-absorbing layer comprising a transparent electrode, a metal oxide layer and a dye adsorbed on the surface of the metal oxide layer.

In the present invention, the metal oxide layer may be made of any one or more selected from the group consisting of, for example, titanium oxide, niobium oxide, hafnium oxide, tungsten oxide, indium oxide, tin oxide and zinc oxide, but is not necessarily limited thereto. These metal oxides may be used alone or in a mixture of two or more. Preferred examples of the metal oxide include TiO₂, SnO₂, ZnO, WO₃, Nb₂O₅, TiSrO₃, or the like, and particularly preferred is anatase-type TiO₂.

The metal oxides forming the light-absorbing layer preferably have a large surface area in order to enable the dye adsorbed on the surface thereof to absorb larger quantities of incident light and to enhance the adhesion thereof to the electrolyte layer. Accordingly, the metal oxides of the light-absorbing layer preferably have nanostructures, such as nanotubes, nanowires, nanobelts, nanoparticles, or the like, or a combination comprising at least one of the foregoing metal oxides.

Examples of the dye are ruthenium complexes such as RuL₂(SCN)₂, RuL₂(H₂O)₂, RuL₃, and RuL₂, wherein L represents 2,2′-bipyridinyl-4,4′-dicarboxylate, or the like, or a combination comprising at least one of the foregoing ruthenium complexes. In addition to the ruthenium complexes, any dye may be used as long as it has a charge separation function and shows photosensitivity. Examples of the dye, which can be used in the present invention, may include xanthine dyes such as rhodamine B, Rose Bengal, eosin or erythrosine, cyanine dyes such as quanocyanine or cryptocyanine, basic dyes such as phenosafranine, capri blue, thiosine or methylene blue, porphyrin type compounds such as chlorophyll, zinc porphyrin, magnesium porphyrin, azo dyes, phthalocyanine compounds, complex compounds such as Ru trispyridyl, anthraquinone-base dyes, polycyclic quinone-base dyes, or the like, or a combination comprising at least one of the foregoing dyes. These dyes may be used alone or in a mixture of two or more.

The transparent electrode may be used in various solar cells. In addition, it may also be used in photoelectrochromic devices, solar cell driven display devices, and the like. The semiconductor electrode, when used in solar cells, can improve photoelectric efficiency, and thus can realize a high-efficiency solar cell.

Another aspect of the present invention relates to a method for manufacturing a transparent electrode for solar cells. To manufacture a semiconductor electrode a photocatalytic compound is coated on a transparent substrate to form a photocatalytic layer. Then, a water-soluble polymer layer is coated on the photocatalytic layer to form a water-soluble polymer layer, after which the photocatalytic layer and the water-soluble polymer layer are selectively exposed to light. The selectively exposed substrate is plated with a metal to form a metal mesh layer. Then, a conductive material is coated on the metal mesh layer to form a conductive layer.

Each step of a method for manufacturing the semiconductor electrode according to the present invention will now be described in detail.

Step of Forming Photocatalytic Layer

A photocatalytic compound is coated on the transparent substrate to form an optically transparent photocatalytic layer. As describe above, before exposure to light, the photocatalytic compound is inactive, but upon irradiation with light such as ultraviolet light, as the exposed portion is capable of reducing activity. Accordingly, in a subsequent step, when the substrate is dipped in an aqueous solution of metal ions, the exposed portion reduces the metal ions thereby causing the metal ions to be uniformly deposited on the substrate surface.

The photocatalytic compound can be dissolved in a suitable solvent such as isopropyl alcohol and coated on the substrate using any method such as spin coating, spray coating, screen printing, or the like, or a combination comprising at least one of the foregoing processes.

After the above coating step, the substrate is heated in a hot plate or a convection oven at a temperature of 200° C. or less for 20 minutes or less so as to form a photocatalytic layer.

Step of Forming Water-soluble Polymer Layer

On the photocatalytic layer formed as described above, a water-soluble polymer compound is coated to form a water-soluble polymer layer. Examples of the water-soluble polymer usable herein may include homopolymers such as polyvinyl alcohol, polyvinyl phenol, polyvinyl pyrrolidone, polyacrylic acid, polyacrylamide, or the like, or blends and copolymers thereof.

The water-soluble polymer is dissolved in water at a concentration of about 2 to about 30 wt %, and the solution is coated on the substrate using a general coating method such as spin coating, followed by heating, thus forming a water-soluble polymer layer. More specifically, the water-soluble polymer is coated on the substrate according to the same coating method used in forming the photocatalytic layer, and then heated at a temperature of 100° C. or less for 5 minutes or less to remove water, thus forming the water-soluble polymer layer. In this regard, the thickness of the water-soluble polymer layer is controlled in a range of about 0.05 to about 0.5 μm.

The water-soluble polymer layer thus formed functions to promote photoreduction upon subsequent exposure to light so as to increase the photocatalytic activity.

Preferably, the water-soluble polymer layer can be treated with a photosensitizer to increase photosensitivity. Photosensitizing compounds usable herein are water-soluble compounds selected from among pigments, organic acids and organic acid salts. More specifically, these compounds may be exemplified by tar pigments, a potassium or sodium salt of chlorophylline, riboflavin or its derivatives, water-soluble annatto, CUS04, caramel, curcumine, cochineal, citric acid, ammonium citrate, sodium citrate, oxalic acid, K-tartrate, Na-tartrate, ascorbic acid, formic acid, triethanolamine, monoethanolamine, malic acid, or the like, or a combination comprising at least one of the foregoing compounds.

Selective Exposure Step

In this step, the photocatalytic layer/water-soluble polymer layer composite structure formed in the above steps is selectively exposed to light to obtain a potential pattern for forming a metal mesh layer. The activated photocatalytic pattern obtained in this step will act as a nucleus for growing metal crystals in the subsequent step of forming a metal mesh layer.

The exposure conditions, such as exposure atmosphere and exposure dose, are not specifically limited, but can be suitably selected depending on the kind of photocatalytic compound used. In order for a transparent electrode to have sufficient transmittance, exposure to light is preferably performed using an UV exposure system at a dose of about 200 to about 1500 W for a period ranging from about 30 seconds to about 5 minutes.

In order to more effectively form a metal mesh pattern, the above-formed potential pattern can be treated with a metal salt solution during the exposure step to obtain a pattern deposited with the metal particle of the metal salt. The metal salt solution used herein may be an Ag salt solution, a Pd salt solution or a mixture thereof.

Step of Forming Metal Mesh Layer

The pattern formed during the last step, is plated with a metal, so that a metal crystal is grown on the patterned nucleus to form a metal mesh layer.

The metal plating is performed by electroless plating or electroplating. Here it is desirable to deposit the pattern with a metal salt solution because the pattern will have higher activity as a catalyst for an electroless plating solution. Crystal growth is thus promoted to provide a more compact metal pattern.

In forming the metal mesh layer as described above, the metal mesh layer can also be formed to have a multilayer structure of at least two layers through continuous metal plating. For example, the multilayer metal mesh structure can be easily obtained by treating the potential pattern obtained in the selective exposure step with one kind of metal so as to form a first metal layer, and then treating at least a portion of the first metal layer with another kind of metal so as to form a second metal layer. In this case, the kinds of the metals and the order of forming the metal layers can be suitably selected depending on circumstances, and the metal layers can be formed of the same or different metals. Also, the thickness of each of the metal layers can be controlled depending on the circumstances.

In order for the multilayer metal mesh structure to have low resistance, it is preferable that the first metal layer be formed with Ni, Pd, Sn, Cr or an alloy thereof to have a thickness of about 0.1 to about 1 μm, and the second metal layer be formed with Cu, Ag, Au or an alloy thereof, having high electrical conductivity, to have a thickness of about 0.1 to about 10 μm. More preferably, the first metal layer is made of nickel in the interests of cost and ease of processability, and the second metal layer is made of Ag or Cu.

The mesh pattern shape of the metal mesh layer, the linewidth or density of the metal mesh layer, and the like, can be controlled to obtain the desired light transmittance, flexibility and mechanical strength of the transparent electrode.

Step of Forming Conductive Layer

On the metal mesh layer formed as described above, an electrically conductive material is coated. The electrically conductive material usable herein is exemplified by indium tin oxide (ITO), fluorine-doped tin oxide (FTO), ZnO-Ga₂O₃, ZnO-A1₂0₃, SnO₂-Sb₂0₃, or the like, or a combination comprising at least one of the foregoing electrically conductive materials. A paste containing this conductive material is prepared and then coated on the metal mesh layer by methods, such as, spraying, spin coating, dipping, printing, doctor blading, sputtering, electrophoresis, or the like, or a combination comprising at least one of the foregoing methods.

In the case of manufacturing a semiconductor electrode for solar cells using the inventive transparent electrode for solar cells, a light-absorbing layer of metal oxide is formed on one surface of the transparent electrode.

The metal oxide for the transparent electrode is selected from the group consisting of, for example, titanium oxide, niobium oxide, hafnium oxide, indium oxide, tin oxide, zinc oxide or the like, or a combination comprising at least one of the metal oxides.

In the forming of the metal oxide layer a wet processing method is preferable in terms of physical properties, convenience, manufacturing costs, or the like. It is preferable to use a method comprising preparing a paste that comprises a metal oxide powder uniformly dispersed in a suitable solvent and coating the paste on the transparent electrode, followed by drying and calcining. In this regard, the coating may be performed using a general coating method, for example, spraying, spin coating, dipping, printing, doctor blading, sputtering, electrophoresis, or the like, or a combination comprising at least one of the foregoing processes.

Thereafter, the metal oxide layer is immersed in a solution containing a photosensitive dye for at least 12 hours to adsorb the dye onto the surface of the metal oxide. The solvent for forming the photosensitive dye-containing solution is exemplified by tertiary butyl alcohol, acetonitrile, or a mixture thereof.

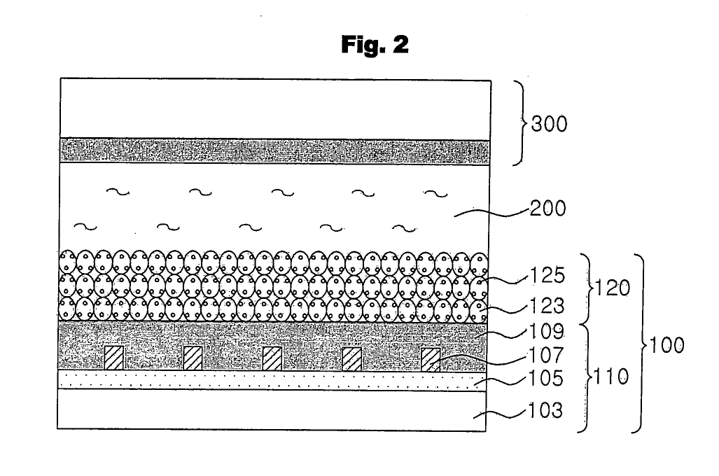

Still another aspect of the present invention relates to a solar cell comprising the semiconductor described herein. FIG. 2 is a schematic cross-sectional view of a dye-sensitized solar cell according to one embodiment of the present invention. The dye-sensitized solar cell comprising the inventive semiconductor electrode comprises a semiconductor electrode 100, an electrolyte layer 200 and a counter electrode 300. The semiconductor electrode comprises a transparent electrode 110 formed on a substrate and a light-absorbing layer 120 formed on the transparent electrode, and the light-absorbing layer 120 comprises a metal oxide 123 and a dye 125 adsorbed on the surface of the metal oxide.

In the solar cell, the electrolyte layer 200 can be formed of an electrolyte solution such as iodine-acetonitrile solution, NMP solution or 3-methoxypropionitrile, or a solid electrolyte such as triphenylmethane, carbazole, N,N′-diphenyl-N,N′-bis(3-methylphenyl)-1,1′-biphenyl-4,4′-diamine (TPD), or the like, or a combination comprising at least one of the foregoing solution. Particularly in the case of a flexible solar cell, the solid electrolyte is preferably used.

The counter electrode 300 is formed by uniformly coating the entire surface of the substrate with an electrically conductive material such as platinum, gold, carbon, carbon nanotubes, or the like, or a combination comprising at least one of the foregoing electrically conductive materials. To enhance redox catalytic effects, the surface of the counter electrode preferably has a large surface area. For example, the platinum is preferably coated with a high surface area electrically conductive material such as carbon black or carbon nanotubes.

The method for manufacturing the inventive dye-sensitized solar cell having the above-described structure is not specifically limited, and any method known in the art may be used without any particular limitation.

Hereinafter, the present invention will be described in further detail with reference to examples. It is to be understood, however, that these examples are for illustrative purposes only and are not to be construed to limit the scope of the present invention.

### EXAMPLE 1

An isopropanol solution of polybutyl titanate (5.0 wt %) was applied on a transparent polyethylene sulfone (PES) by spin coating at 2000 revolutions per minute (rpm) and dried on a hot plate at 100° C. for 3 minutes, thus forming a photocatalytic layer having a thickness of about 50 nm. 10 grams (g) of polyvinyl alcohol (a molecular weight of 6000), 12 g of citric acid, 1.0 ml of triethanolamine and 15 ml of isopropyl alcohol were dissolved in 200 ml of distilled water, and the solution was spin-coated on the photocatalytic layer at 2000 rpm and dried on a hot plate at 100° C. for 5 minutes, thus forming a water-soluble polymer layer having a thickness of about 200 nm. The resulting substrate having the photocatalytic layer formed thereon was irradiated with 500 W of ultraviolet light having a broad wavelength range by means of a UV exposure system (Oriel Co. USA) through a photomask having fine patterns formed thereon. After exposure to light, the substrate was immersed in a solution of 0.3 g PdCl₂ and 1 milliliter (ml) KCl in 1 liter of water for 1.5 minutes to allow the Pd metal particle to be deposited on the exposed portion, thus forming a metal mesh layer having a mesh pattern deposited with Pd. At this time, the water-soluble polymer layer was completely washed out while immersing the substrate in the aqueous Pd solution. On the metal mesh layer, a paste of indium tin oxide particles was spin-coated, and the resulting structure was dried at 230° C. for 30 minutes, thus manufacturing the inventive transparent electrode.

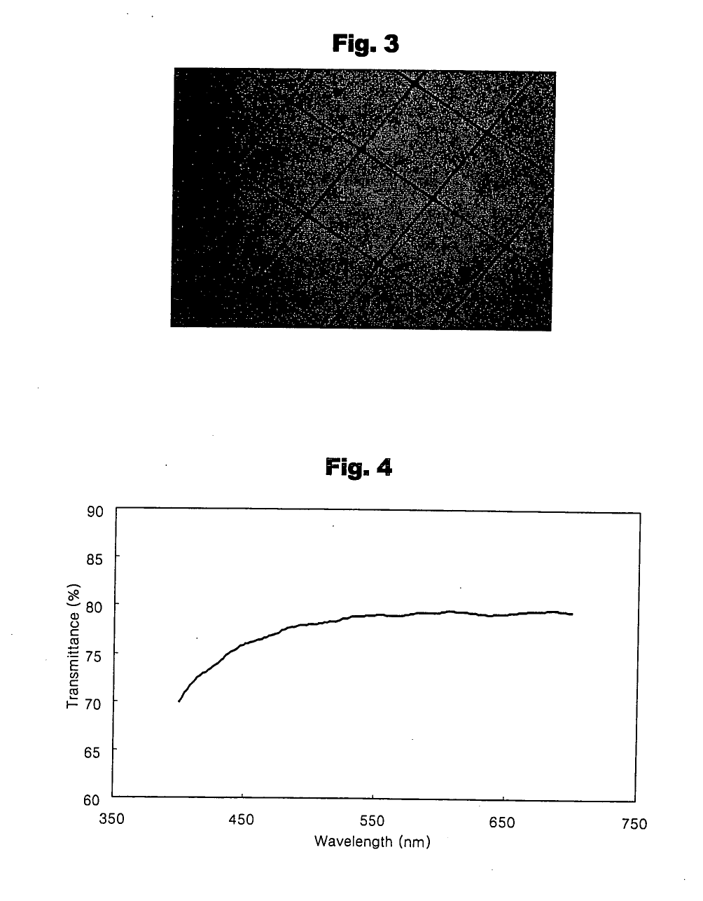

A photograph of the transparent electrode manufactured in this Example is shown in FIG. 3. As shown in FIG. 3, the inventive transparent electrode has a mesh pattern having a plurality of openings.

### Comparative Example 1

Indium tin oxide (ITO) was applied on a glass substrate by means of a sputter, thus manufacturing a transparent electrode for solar cells according to the prior art.

Evaluation of Properties of Transparent Electrodes

Measurement of Transmittance

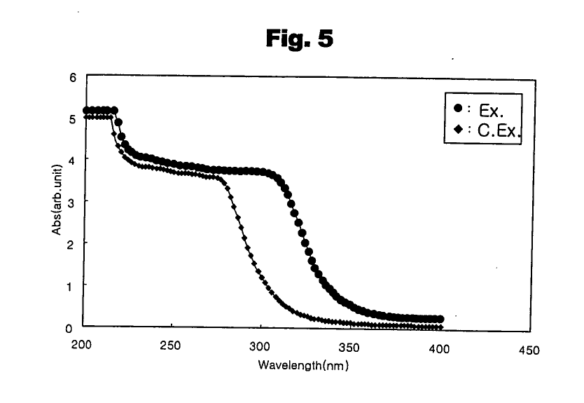

The transmittance of the transparent electrode manufactured in Example 1 and the measurement results are shown in FIG. 4. In this case, the transmittance was measured using a UV-visible spectrophotometer. As can be seen in FIG. 4, the inventive transparent electrode for solar cells showed a transmittance of at least 75%.

Measurement of Absorbance

The transparent electrode manufactured in Example was measured for UV absorbance over a broad wavelength range using a UV spectrophotometer, and the measurement results are shown in FIG. 5. For comparison, the transparent electrode manufactured by coating indium tin oxide on the transparent substrate in Comparative Example was also measured for UV absorbance, and the measurement results are shown in FIG. 5.

Referring to FIG. 5, it can be seen that the inventive transparent electrode has a UV blocking effect due to the absorption by the photocatalytic layer over the entire wavelength range. However, at wavelengths below 260 nm or above 350 nm, the UV absorbance of the inventive transparent electrode was slightly higher than that of the prior transparent electrode (Comparative Example 1), but at a wavelength between 260 nm and 350 nm, the inventive transparent electrode showed a remarkable increase in UV absorbance.

As described above, the inventive transparent electrode for solar cells includes the low-resistance metal mesh layer formed in the existing transparent electrode, and thus has low-resistance properties without a reduction in transmittance. Accordingly, a solar cell that utilizes the inventive transparent electrode has high-efficiency characteristics. The inventive low-resistance transparent electrode including the metal mesh layer can provide uniform and stable solar cell efficiency in large-size applications.

The photocatalytic layer in the inventive transparent electrode has a high UV-blocking effect, and therefore reduces the decomposition of a dye and an electrolyte due to UV light, thus increasing the life cycle of solar cells.

According to the inventive method for manufacturing a transparent electrode for solar cells, a transparent electrode having low resistance and high conductivity can be effectively manufactured in a short time without being subjected to, for example, a sputtering process, which requires high-vacuum conditions.

Although a preferred embodiment of the present invention has been described for illustrative purposes, those skilled in the art will appreciate that various modifications, additions and substitutions are possible, without departing from the scope and spirit of the invention as disclosed in the accompanying claims.

What is claimed is:

1. A transparent electrode for solar cells, comprising:
a transparent substrate;
a photocatalytic layer formed on the transparent electrode and comprising a photocatalytic compound;
a metal mesh layer formed on the photocatalytic layer; and
an electrically conductive layer formed of an electrically conductive material coated on the metal mesh layer.

2. The transparent electrode of claim 1, wherein the photocatalytic compound is a Ti-containing organometallic compound.

3. The transparent electrode of claim 2, wherein the Ti-containing organometallic compound is tetraisopropyltitanate, tetra-n-butyl titanate, tetrakis(2-ethyl-hexyl)titanate, polybutyltitanate, or a combination comprising at least one of the foregoing organometallic compounds.

4. The transparent electrode of claim 1, wherein the photocatalytic layer has a thickness of about 10 to about 100 nm.

5. The transparent electrode of claim 1, wherein the metal mesh layer has a multilayer structure comprising at least two layers made of different metals.

6. The transparent electrode of claim 5, wherein the metal mesh layer comprises a first metal mesh layer formed of Ni, Pd, Sn, Cr or an alloy thereof and a second metal mesh layer formed of Cu, Ag, Au or an alloy thereof.

7. The transparent electrode of claim 1, wherein the electrically conductive material of the electrically conductive layer is selected from the group consisting of indium tin oxide (ITO), fluorine-doped tin oxide (FTO), ZnO-Ga₂O₃, ZnO-Al₂0₃, SnO₂-Sb₂O₃, and a combination comprising at least one of the foregoing electrically conductive materials.

8. A method for manufacturing a transparent electrode for solar cells, which comprises:
coating a photocatalytic compound on a transparent substrate to form a photocatalytic layer;
coating a water-soluble polymer layer on the photocatalytic layer to form a water-soluble polymer layer;
selectively exposing the photocatalytic layer and the water-soluble polymer layer to light through a photomask;
plating the exposed substrate with a metal to form a metal mesh layer; and
coating an electrically conductive layer on the metal mesh layer to form an electrically conductive layer.

9. The method of claim 8, wherein the photocatalytic compound is a Ti-containing organometallic compound selected from the group consisting of tetraisopropyltitanate, tetra-n-butyl titanate, tetrakis(2-ethyl-hexyl)titanate, polybutyltitanate, and a combination comprising at least one of the foregoing organometallic compounds.

10. The method of claim 8, wherein the water-soluble polymer compound is selected from the group consisting of polyvinyl alcohol, polyvinyl phenol, polyvinyl pyrrolidone, polyacrylic acid, polyacrylamide, gelatin and a a combination comprising at least one of the foregoing water-soluble polymer compounds.

11. The method of claim 8, wherein the water-soluble polymer layer comprises a photosensitizer selected from the group consisting of tar pigment, a potassium or sodium salt of chlorophylline, riboflavine and its derivatives, water-soluble annatto, CuS0₄, caramel, curcumine, cochinal, citric acid, ammonium citrate, sodium citrate, oxalic acid, K-tartrate, Na-tartrate, ascorbic acid, formic acid, triethanolamine, monoethanolamine, malic acid, and a combination comprising at least one of the foregoing water soluble polymers.

12. The method of claim 8, which additionally comprises the step of treating the selectively exposed substrate with a metal salt solution to obtain a pattern having the metal deposited on a potential pattern formed on the exposed portion.

13. The method of claim 12, wherein the metal salt solution is a palladium salt solution, a silver salt solution, or a mixture thereof.

14. The method of claim 8, wherein the step of forming the metal mesh layer comprises:
subjecting the selectively exposed substrate to electroless plating with a metal selected from among Ni, Pd, Sn, Cr or an alloy thereof so as to form a first metal mesh layer; and
subjecting the first metal mesh layer to electroplating or electroless plating with Cu, Ag, Au or an alloy thereof so as to form a second metal mesh layer.

15. The method of claim 8, wherein the electrically conductive material is selected from the group consisting of indium tin oxide (ITO), fluorine-doped tin oxide (FTO), ZnO-Ga₂O₃, ZnO-Al₂O₃, SnO₂-Sb₂O₃, and a combination comprising at least one of the foregoing electrically conductive materials.

16. A semiconductor electrode for solar cells, comprising a transparent electrode as set forth in claim 1, a metal oxide layer and a dye adsorbed on the surface of the metal oxide layer.

17. A dye-sensitized solar cell comprising a semiconductor electrode as set forth in claim 16.
